(19) United States
(12) Patent Application Publication
(10) Pub. No.: US 2021/0080492 A1
(43) Pub. Date: Mar. 18, 2021

(54) SEMICONDUCTOR DEVICE AND POWER DEVICE

(71) Applicant: RENESAS ELECTRONICS CORPORATION, Tokyo (JP)

(72) Inventors: Naohiro YOSHIMURA, Tokyo (JP); Makoto TANAKA, Tokyo (JP)

(21) Appl. No.: 16/943,429

(22) Filed: Jul. 30, 2020

(30) Foreign Application Priority Data
Sep. 17, 2019 (JP) 2019-168866

(51) Int. Cl. G01R 19/165; H03K 5/24; H03K 3/037

(52) U.S. Cl. CPC G01R 19/16571; H03K 3/037; H03K 5/24

(57) ABSTRACT

A semiconductor device includes an output transistor that supplies a power to a load, a sense transistor that detects a load current of the output transistor, first and second transistors connected in parallel to an output of the sense transistor, an amplifier which has an inverting input coupled to an output of the output transistor, a non-inverting input coupled to the output of the sense transistor, and an output coupled to each gate of the first and second transistors, a first voltage converter coupled to an output of the first transistor, and a comparator that compares an output voltage of the first voltage converter with a predetermined voltage.

### CROSS-REFERENCE TO RELATED APPLICATIONS

The disclosure of Japanese Patent Application No. 2019-168866 filed on Sep. 17, 2019 including the specification, drawings and abstract is incorporated herein by reference in its entirety.

### BACKGROUND

It relates to semiconductor device, and more particularly to IPD (Intelligent Power Device).

An IPD is used to drive loads such as automobile motors and LEDs (Light Emitting Diode). In IPD, a chip composed of power MOSFET or IGBT (Insulated Gate Bipolar Transistor) for supplying power to loads and a chip composed of control circuits for controlling power MOSFET are one package.

When driving a load with IPD, the current flowing through the load, i.e., the current flowing through the power MOSFET, needs to be monitored for two reasons. The first reason is to control the load current with high accuracy. For example, if the load is a motor, PWM control is performed so that the current flowing through the load becomes a predetermined current value. Therefore, it is required to detect the current flowing in the power MOSFET with high accuracy. Another reason is for overcurrent protection. For example, if a short circuit fault occurs in the load, overcurrent may flow through the power MOSFET and the power MOSFET would be damaged. Therefore, it is required to detect whether a current equal to or greater than a predetermined value is flowing through the power MOSFET.

Patent Document 1 describes a technique for detecting the loading current. In addition, Patent Document 2 and Patent Document 3 describe a technique for detecting an overcurrent.

### PRIOR-ART DOCUMENT

### Patent Document

[Patent Document 1] Japanese Unexamined Patent Application Publication No. 2016-200570

[Patent Document 2] Japanese Unexamined Patent Application Publication No. 2013-255117

[Patent Document 3] Japanese Unexamined Patent Application Publication No. 2010-193034

### SUMMARY

In either Patent Document, detecting the current flowing in the power MOSFET is performed using a sense MOS provided in parallel with the power MOSFET. Although there is no description of a technique for simultaneously realizing the detection of the load current and the detection of overcurrent described above, it is possible to realize the two current detections by providing two sense MOS. However, this leads to circuit area increasing.

Other objects and novel features will become apparent from the description of the specification and drawings.

### Means of Solving the Problems

A semiconductor device according to an embodiment includes: an output transistor that supplies a power to a load, a sense transistor that detects a load current of the output transistor, first and second transistors connected in parallel to an output of the sense transistor, an amplifier which has an inverting input coupled to an output of the output transistor, a non-inverting input coupled to the output of the sense transistor, and an output coupled to each gate of the first and second transistors, a first voltage converter coupled to an output of the first transistor, and a comparator that compares an output voltage of the first voltage converter with a predetermined voltage.

In semiconductor device according to an embodiment, it is possible to reduce the circuit area in semiconductor device with output current detection and/or overcurrent detection.

### BRIEF DESCRIPTION OF THE DRAWINGS

FIG. 1 is a schematic diagram of an electronic control device according to a first embodiment.

FIG. 2 is a schematic diagram of an IPD according to the first embodiment.

FIG. 3 is a schematic diagram of an SR-latch according to the first embodiment.

FIG. 4 is a schematic diagram of a constant-voltage source according to the first embodiment.

FIG. 5 is a schematic diagram of a constant-voltage source according to the first embodiment.

FIG. 6 is a structural diagram of IPD according to the first embodiment.

FIG. 7 is a cross-sectional view of IPD according to the first embodiment.

FIG. 8 is a timing chart showing the operation of the IPD according to the first embodiment.

FIG. 9 is a timing chart showing the operation of the IPD according to the first embodiment.

FIG. 10 is a schematic diagram of an electronic control device according to a first modified embodiment.

FIG. 11 is a schematic diagram of an IPD according to a second modified embodiment.

FIG. 12 is a timing chart showing the operation of the IPD according to the second modified embodiment.

FIG. 13 is a timing chart showing the operation of the IPD according to the second modified embodiment.

FIG. 14 is a schematic diagram of an IPD according to a second embodiment.

FIG. 15 is a diagram showing connections of IPD according to the second embodiment.

FIG. 16 is a diagram showing connections of IPD according to the second embodiment.

FIG. 17 is a diagram showing connections of IPD according to the second embodiment.

FIG. 18 is a diagram showing connections of IPD according to the second embodiment.

FIG. 19 is a diagram showing connections of IPD according to the second embodiment.

FIG. 20 is a diagram showing connections of IPD according to the second embodiment.

### DETAILED DESCRIPTION

Hereinafter, a semiconductor device according to an embodiment will be described in detail by referring to the drawings. In the specification and the drawings, the same or corresponding form elements are denoted by the same reference numerals, and a repetitive description thereof is omitted. In the drawings, for convenience of description, the configuration may be omitted or simplified. Also, at least some of the embodiments may be arbitrarily combined with each other.

### First Embodiment

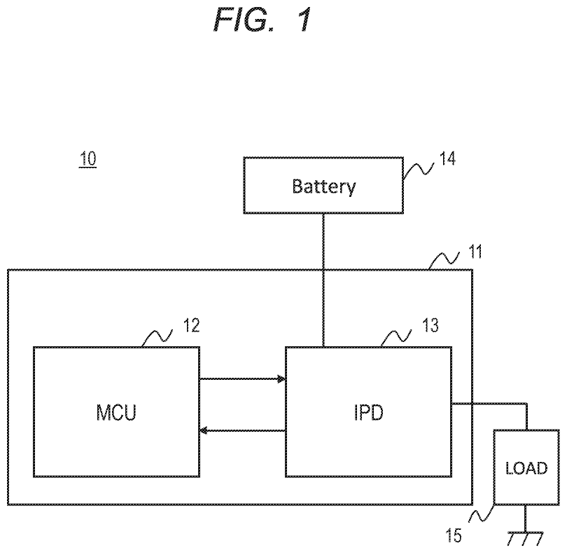

FIG. 1 is a block diagram showing a configuration of an electronic control device 10 according to the first embodiment.

The electronically controlled device 10 is comprised of a power control unit 11, a battery 14, and loads 15, as shown in FIG. 1. The power control unit 11 is, for example, an in-vehicle ECU (Electronic Control Unit), and includes an MCU (Micro Control Unit) 12 and an IPD (Intelligent Power Device) 13.

IPD 13 is powered from a battery or upstream power control unit and controls the power supply to the loads 15 by control from MCU 12. IPD 13 is a power device having a power semiconductor device such as a power MOSFET or an IGBT, a control circuit, an output circuit. The detailed later.

MCU 12 outputs a control signal to IPD 13 so that the load (e.g., motor or LED) to be controlled becomes a desired operation. In addition, when controlling, it refers to the output signal from IPD 13 (feedback signal). The detailed later.

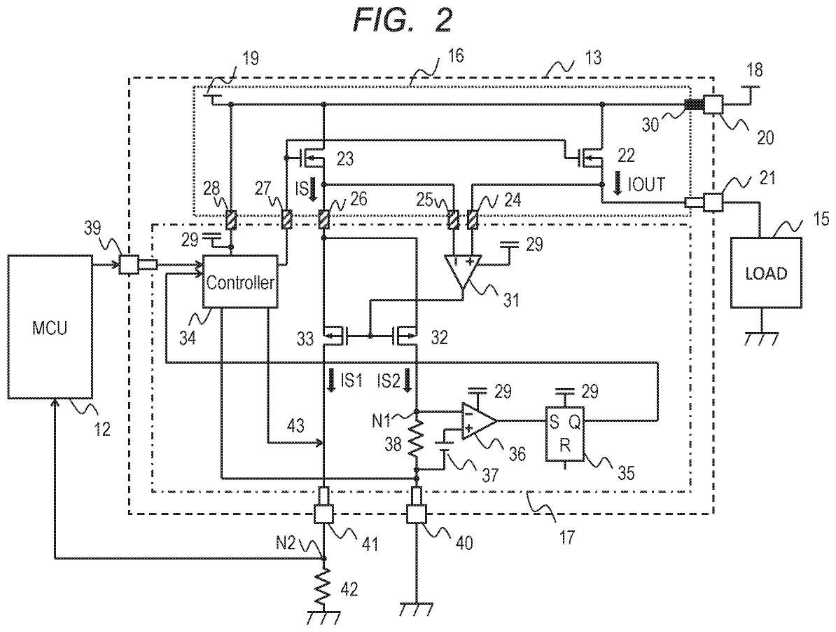

FIG. 2 is a detailed schematic diagram of IPD 13. IPD 13 comprises an output circuit and a control circuit. In present embodiment, since each of the output circuit and the control circuit is constituted by a separate chip, each of the first chip (hereinafter, referred to as an output chip) 16, a second chip (hereinafter, referred to as a control chip) 17. The output chip 16 and the control chip 17 are connected by inter-chip bonding wires 24-28.

The output chip 16 is a circuit for providing power to the load 15 and has a first power transistor 22. Furthermore, a second power transistor 23 for detecting the output current to the load 15 in the control chip 17 to be described later. Although the first power transistor 22 and the second power transistor 23 is constituted by a power MOSFET or IGBT, for simplicity here, they are referred to as an output MOS 22 and a sense MOS 23, respectively. The output MOS 22 is an output transistor that provides direct power to the loads 15. The sense MOS 23 is a sense transistor for detecting the load current flowing in the output MOS 22. Here, the sense MOS 23 is similar to the output MOS 22, i.e., only the channel width is different, the cross-sectional structure and the property per unit channel width is equal.

External power supply 18 (battery and upstream power control unit) is connected to the power supply terminal 20. Output chip power supply 19 is a power supply and supplies a power supply voltage from the external power supply 18 to the output MOS 22 and the sense MOS 23. Present embodiment uses a so-called vertical power-device configuration, which will be described later in detail. Since the drain of the output MOS 22 and the sense MOS 23 will be located on the rear surface of the device, the output chip power supply 19 and the power supply terminal 20 is connected via the rear surface (rear surface connection 30).

The drain of the output MOS 22 is connected to the output chip power supply 19, and the gate is connected to the controller 34 of the control chip via an inter-chip bonding wire 27. The drain and gate of the sense MOS 23 are also similar to the output MOS 22. An output signal of the output MOS 22 is output to a load 15 connected to the output terminal 21 and control chip 17 via the chip-to-chip bonding wire 24. The output signal of the sense MOS 23 is output to the control chip 17 via the inter-chip bonding wires 25 and 26.

The output chip power supply 19 is connected to the control chip 17 via an inter-chip bonding wire 28 and is used as a control chip power supply 29. The control chip power 29 is supplied to each circuit to be described later in the control chip 17.

Next, the control chip 17 will be described. Control chip 17 is a circuit for controlling the output chip 16 and detects an output current to the load 15. Control chip 17 includes an amplifier 31, P-type transistors 32, 33, the controller 34, SR latch 35, the comparator 36, a constant voltage source 37, a first voltage converter (hereinafter, referred to as a resistor) 38. P-type transistor 32 can be said to be a second transistor, P-type transistor 33 can be said to be a first transistor.

Controller 34, in response to a control signal from MCU 12 connected to the input terminal 39, generates a gate drive signal of the output MOS 22 and the sense MOS 23. Although the gate drive signal is actually generated by the charge pump, it is omitted in FIG. 2. The controller 34, based on the output signal of the SR latch 35, also has a function of determining whether the output MOS 22 is in an overcurrent output state. If it is determined that the overcurrent output state, the controller 43 outputs an abnormality signal 43 to MCU 12 from the external terminal 41 which is an output terminal. The detailed later.

The sources of transistors 32 and 33 are connected in parallel to a source (output) of the sense MOS 23 via an inter-chip bonding wire 26. The drain of transistor 32 is connected to one end of resistor 38. The other end of the resistor 38 is connected to the controller 34 and is connected to the external terminal 40 via a lead-to-chip bonding wire. External terminal 40 is connected to the ground. The drain of the transistor 33 is connected to the external terminal 41 through the lead-chip bonding wire. External terminal 41 is connected to the MCU 12 and the ground via the second voltage converter (hereinafter, referred to as an external resistor) 42.

One end of the resistor 38 (node N1) is connected to a minus terminal of the comparator 36. The other end of the resistor 38 is connected to a plus terminal of the comparator 36 via a constant voltage source 37. The output of the comparator 36 is connected to the S (set) terminal of the SR latch 35. The Q output of the SR latch is connected to the controller 34.

The non-inverting input (+) of the amplifier 31 is connected to a source (output) of the output MOS 22 via the inter-chip bonding wire 24. The inverting input (−) of the amplifier 31 is connected to a source (output) of the sense MOS 23 via an inter-chip bonding wire 25. The output of amplifier 31 is connected to the gate of transistors 32 and 33.

Here, focusing on the connection relationship between the amplifier 31 and the transistors 32 and 33, the amplifier 31 has a negative feedback through the transistors 32 and 33. Thus, due to the imaginary short, the amplifier 31 controls the gate voltage of the transistors 32, 33 so that the non-inverting input (source of the output MOS 22) and the inverting input (source of the sense MOS 23) are at the seine potential. As a result, the source of the output MOS 22 and the source of the sense MOS 23 are at the same potential, the drain of the output MOS 22 and the drain of the sense MOS 23 are at the same potential, and the gate of the output MOS 22 and the gate of the sense MOS 23 are at the same potential. As noted above, the output MOS 22 and sense MOS 23 differ only in the channel width. Assuming that the channel width of the output MOS 22 is W22 and the channel width of the sense MOS 23 is W23, the relation between the current IOUT flowing in the output MOS 22 and the current IS flowing in the sense MOS 23 is IS=IOUT×W23/W22 (Equation 1).

The current IS flowing in the sense MOS 23 diverts to the transistors 32, 33. When a current flowing through the transistor 33 is IS1 and a current flowing through the transistor 32 is IS2, IS=IS1+IS2 (Equation 2). Further, gates and sources of the transistors 32 and 33 are common. The transistor 32 and 33 are similarity structure except for the channel width. When a channel width of the transistor 32 is W32 and a channel width of the transistor 33 is W33, IS2=IS1×W32/W33 (Equation 3).

(Equation 2) (Equation 3) gives IS1=IS/(1+W32/W33). When a resistance value of the external resistor 42 is R42, a voltage output to the MCU (voltage of the node N2) is R42×IS1=R42×IS/(1+W32/W33). This is R42×(IOUT×W23/W22)/(1+W32/W33) according to (Equation 1), Therefore, MCU 12 can calculate the current IOUT from the outputted voltage values. MCU 12 can increase the control accuracy of the loads 15 by detecting the current IOUT. It should be noted that, of course, the measurement of the voltage value, A/D converter built-in or external MCU 12 (both not shown) is used.

Next, attention is paid to the comparator 35. When the resistance value of the resistor 38 is R38, the voltage of the-terminal of the comparator 35 (voltage of the node N1) is R38×IS2. This becomes R38×(IOUT×W23/W22)/(1+W33/W32) from (Formula 1) (Formula 2) (Formula 3) Therefore, by setting the voltage V37 of the constant voltage source 37 to a predetermined value, the comparator 35 detects whether or not the current IOUT is equal to or greater than a predetermined value (a value determined by R38, W22, W23, W32, and W33). In present embodiment, the voltage V37 is set to a voltage that can detect that a short-circuit failure has occurred in the load 15. When a short-circuit failure in the load 15, for example, a ground fault occurs, a large current flows toward the ground from the output terminal 21, the current IOUT is increased (overcurrent output state). When the voltage V37 is set to a voltage value that cannot be generated in normal operation, it is possible to detect a short-circuit failure of the load 15. That is, in accordance with the comparison result of the comparator 36, it is possible to detect an overcurrent to the load 15.

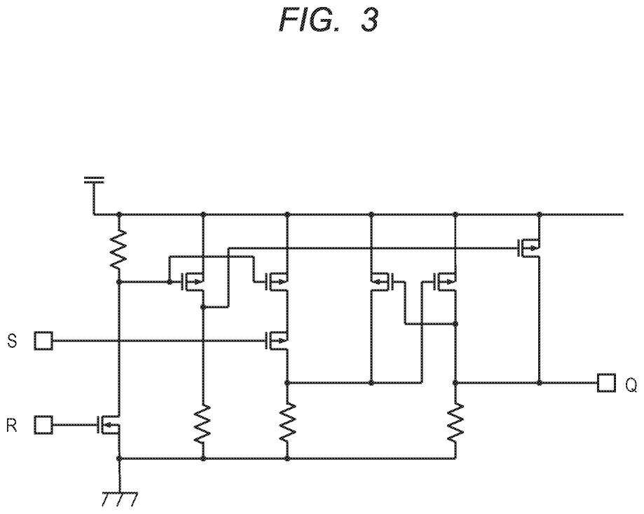

S (set) terminal of the SR latch 35 receives the output signal of the comparator 36. R (reset) terminal of SR latch 35 receives the reset signal from MCU 12 (not shown). FIG. 3 is an example of the SR latch 35. As shown in FIG. 3, when the R terminal is at a low level (hereinafter, referred to as Lo), the SR latch 35 outputs a high level (hereinafter, referred to as Hi) (reset state). When R terminal is High and S terminal is High, the SR latch 35 outputs Hi but does not latch the Hi. When the R terminal is Hi and the S terminal is Lo, the SR latch 35 outputs Lo and latches the Lo. That is, even if the S terminal is changed from Lo to Hi in a state of latching the Lo, output of the SR latch remains Lo. That is, SR latch 35, after being reset by MCU 12, will latch Lo when the comparator 36 detects a status, V37<R38×IS2. In present embodiment, as described above, when a short-circuit failure occurs in the load 15, Lo will be latched in the SR-latch 35.

Suppose transistors 32 and 33 have current capabilities that exceed the current values that a sense MOS 23 can flow through. The resistor 38 is for voltage-converting the current IS2, it may be used a depletion NOS transistor having a gate-drain short.

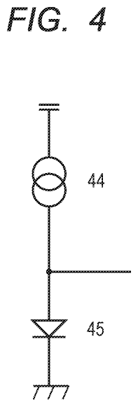

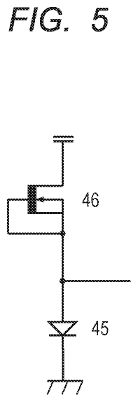

FIG. 4 shows an example of the constant voltage source 37. The constant voltage source 37 outputs a voltage between a constant current source 44 connected to the control chip power supply 29 and a diode 45 whose cathode is coupled to the ground as output voltage. FIG. 5 is an example of the constant voltage source 37. In this case, a depletion NMOS transistor 46 whose gate and source are coupled is used as the constant current source 44.

The controller 34 will be described again. As described above, SR latch 35 latches Lo when a short circuit fault occurs in the load 15. Controller 34, in response to Lo latched in the SR latch 35, can detect the overcurrent output state. The controller 34, upon detecting the overcurrent output state, turns off the output MOS 22, and outputs the abnormality signal 43 from the output terminal 41 to MCU 12.

Next, MCU 12 will be described. MCU 12 outputs a control signal from the input terminal 39 to the controller 34 such that the load 15, such as a motor or LED, is in the desired operation. For example, PID (Proportional-Integral-Differential) control is performed. For PID control, MCU 12 uses the voltage value at one end (node N2) of the external resistor 42. This is because, as described above, MCU 12 can detect the output current IOUT to the load 15 from the voltage value of the node N2.

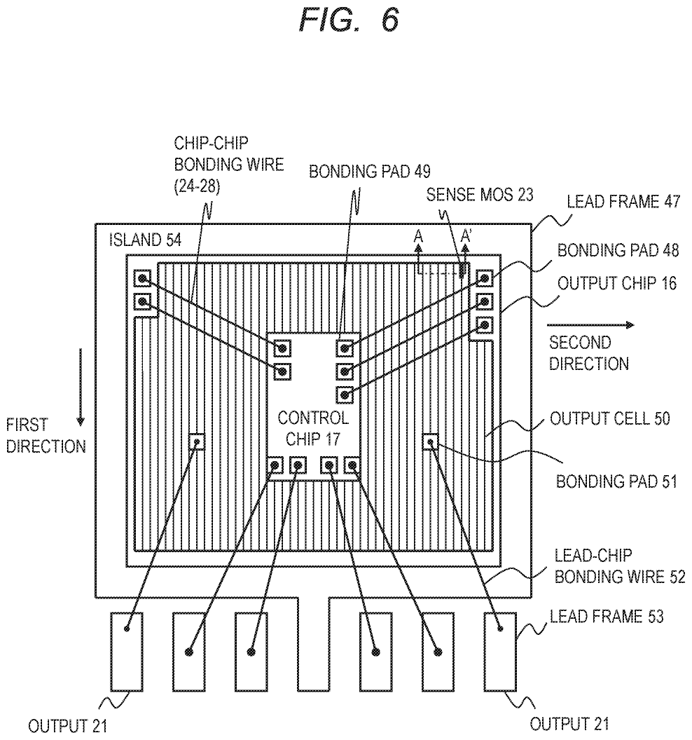

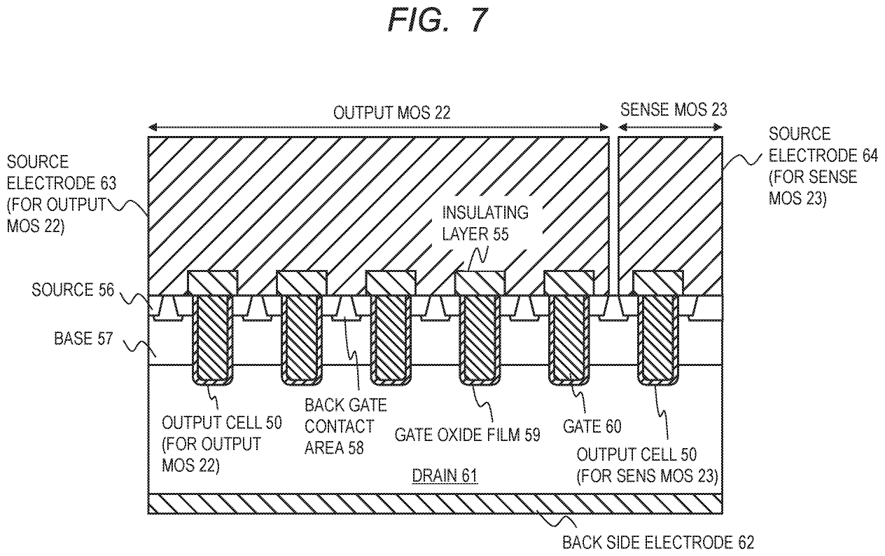

FIGS. 6 and 7 show the construction of IPD 13 according to present embodiment. As shown in FIG. 6, IPD 13 in present embodiment includes a lead frame 47, the output chip 16, and the control chip 17. The output chip 16 is mounted on the island 54 of the lead frame serving as the power supply terminal 20. The output chip 16 has a plurality of output cells 50. The output cells 50 extend in a first direction and are arranged to line up along a second direction. Each of the plurality of output cells 50, via the bonding pad 51 and the lead-chip bonding wire 52 is connected to the lead frame 53 serving as an output terminal 21.

As also described in FIG. 2, five bonding pads 48 of the output chip 16 and five bonding pads 49 of the control chip 17 are connected by chip-chip bonding wires 24-28.

FIG. 7 is a cross-sectional view between A-A′ of FIG. 6. As shown in FIG. 7, the output-chip 16 is comprised of semiconductor substrate. Semiconductor substrate has a drain region 61, a base region 57, a plurality of gate electrodes 60, a back gate contact area 58, a source region 56. On the back side of the drain region 61, the back electrode 62 is provided. Base region 57 is provided on the main surface of the drain region 61. Each of the plurality of gate electrodes 60 is a trench structure is formed so as to reach the drain region 61 from the main surface side of the base region 57.

Each gate electrode 60 is covered by a gate oxide film 59. A back gate contact area 58 is provided at the central between adjacent gate electrodes 60. A source region 56 is provided between the back gate contact area 58 and each gate electrode 60. On the main surface of semiconductor substrate, a source electrode 63 for output MOS 22, and a source electrode 64 for sense MOS 23 is provided. The source electrode 63 and the source electrode 64 are separated from each other. The source electrodes 63, 64 are in contact with the back gate contact area 58 and the source region 56. However, an insulating layer 55 is provided so that the source electrodes 63 and 64 do not contact the gate 60. The output MOS 22 is not limited to MOSFET, it is possible to use an IGBT or the like.

The control chip 17 is also constructed of semiconductor substrate and is bonded across an insulator over the output chip 16. The control chip 17 is composed of common CMOS elements, capacitors, diodes, resistors, and the like, and does not have an output cell such as the output chip 16.

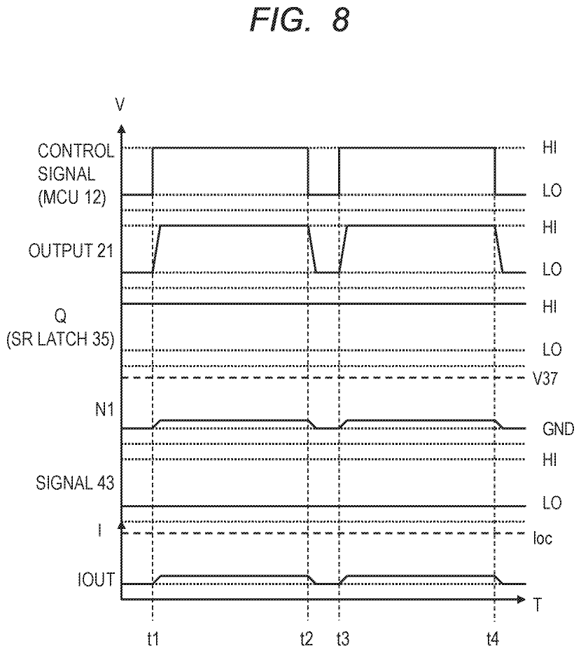

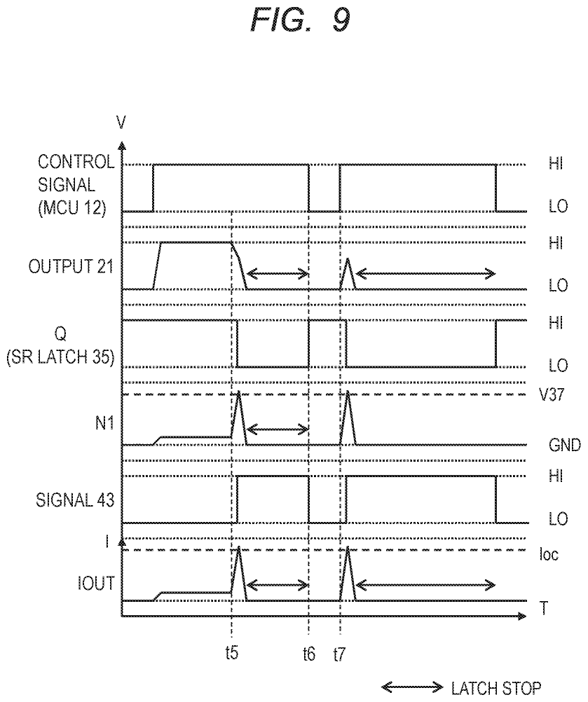

Next, the operation of IPD 13 according to present embodiment will be described. FIG. 8 is a timing chart at the time of normal operation of IPD 13. Further, FIG. 9 is a timing chart of IPD 13 when a short-circuit failure occurs in the load 15.

First, the normal operation of IPD 13 will be described with reference to FIG. 8. MCU 12 outputs a control signal from the input terminal 39 to the controller 34 such that the load 15 is in the desired operation. In FIG. 8, at time t1 to t2, t3 to t4, MCU 12 outputs the control signal Hi to apply a current to the load 15.

Controller 34 which has received the control signal from MCU 12 outputs a gate drive signal to the output MOS 22 and the sense MOS 23 via the chip-to-chip bonding wire 27. The output MOS 22 apply a current to the load 15 in response to the gate drive signal. In FIG. 8, in response to the control signal that becomes Hi at t1 to t2, t3 to t4, the current IOUT flows and the voltage of the output terminal 21 is Hi.

In the load 15 is in the normal state, the current IOUT is not an overcurrent, is equal to or less than the overcurrent detection threshold (Ioc) for determining the overcurrent. The voltage of the node N1 is also equal to or lower than the voltage V37 corresponding to Ioc. Therefore, the SR latch 35 remains Hi.

Since the SR latch 35 remains Hi, the controller 34 outputs Lo as the abnormality signal 43 and continues the control for the load 15.

Next, a case where a short-circuit failure occurs in the load 15 will be described with reference to FIG. 9. FIG. 9 shows that a short circuit fault (ground fault) occurred in the load 15 at time t5. When a short-circuit failure occurs in the load 15, the voltage of the output terminal 21 is lowered and the current IOUT is rapidly increased. When the current IOUT exceeds the overcurrent detection threshold, the voltage of the node N1 also exceeds the increased voltage V37 and Lo is latched to the SR latch 35.

When SR latch 35 is Lo, i.e., the overcurrent output state is detected, the controller 34 turns off the gate drive signal to the output MOS 22 and the sense MOS 23 and outputs an abnormality signal 43 to MCU 12.

At time t6, when the control signal from MCU 12 is Lo, SR latch 35 is reset to Hi.

When the control signal from MCU 12 becomes Hi again during the short-circuit failure (time t7), the current IOUT is rapidly increased again, the SR latch 35 latches Lo and the controller 34 outputs an abnormal signal 43 to MCU 12.

As described above, in the electronic control device 10 according to present embodiment, the output current of the sense MOS 23 (IS) is divided into two current IS1 and IS2 using the amplifier 31, the transistors 32 and 33. By using the current IS1 as a sensing of the output current (IOUT) to the load 15 and using the current IS2 as an overcurrent sensing, it is possible to reduce the chip area and the number of chip-to-chip bonding wires and bonding pads.

### First Modified Embodiment

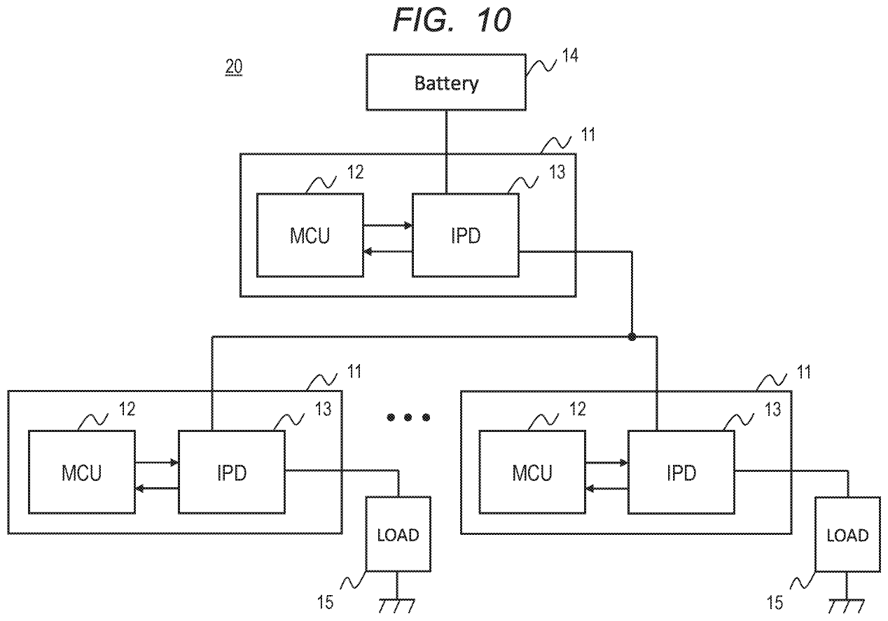

FIG. 10 is a block diagram showing the configuration of the electronic control device 10a according to the first modified embodiment.

As shown in FIG. 10, present embodiment allows one power control unit 11 to provide power to other power control units 11. In this instance, only the control method for the loads 15 are changed, and the same configuration and operation as those of IPD 13 in first embodiment are applied.

### Second Modified Embodiment

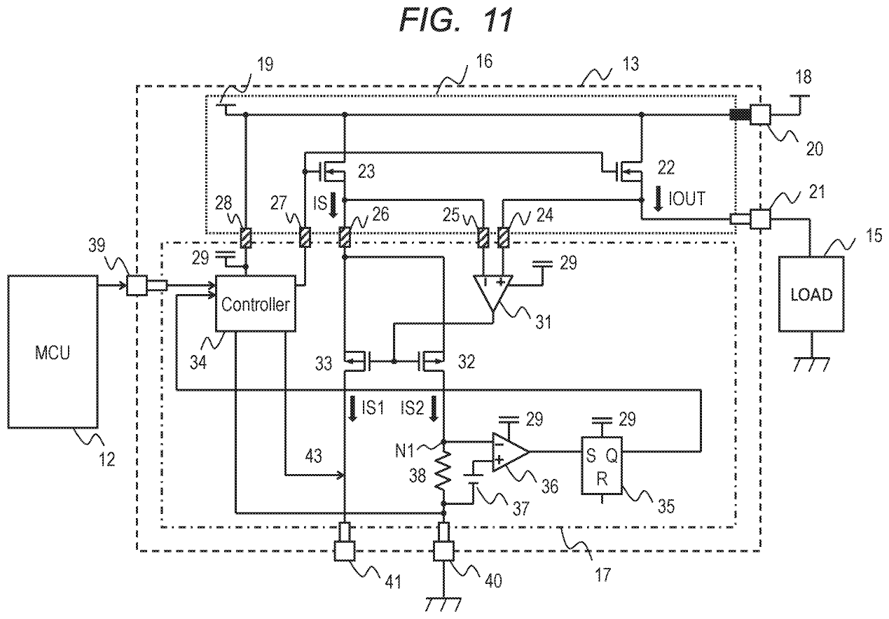

FIG. 11 is a schematic diagram of an IPD 13 according second modified example. The difference from FIG. 2 is that the external terminal 41 is not connected to MCU 12. Configuration other than the external terminal 41 is the same as in FIG. 2.

Since the external terminal 41 is not connected, during operation, the current IS1 becomes 0, the current IS2=IS. The range of the current values of the current IS2 is enlarged as compared with first embodiment. In other words, even if the current IOUT changes narrowly, the current IS2 changes widely. This makes it possible to detect an overcurrent outputting state even when the current IOUT is lower than that of first embodiment.

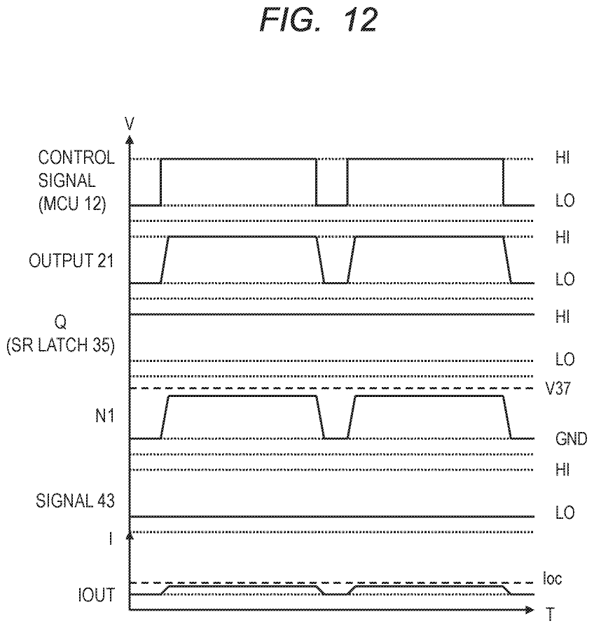

FIG. 12 is a timing chart in the normal state in second modified example. The difference from FIG. 8 is a voltage change at node N1. Compared to FIG. 8, in FIG. 12, even if the current IOUT is slightly increased, the voltage rises to the vicinity of the voltage V37. This is because the current IS2 is increased in second modified example compared to first embodiment.

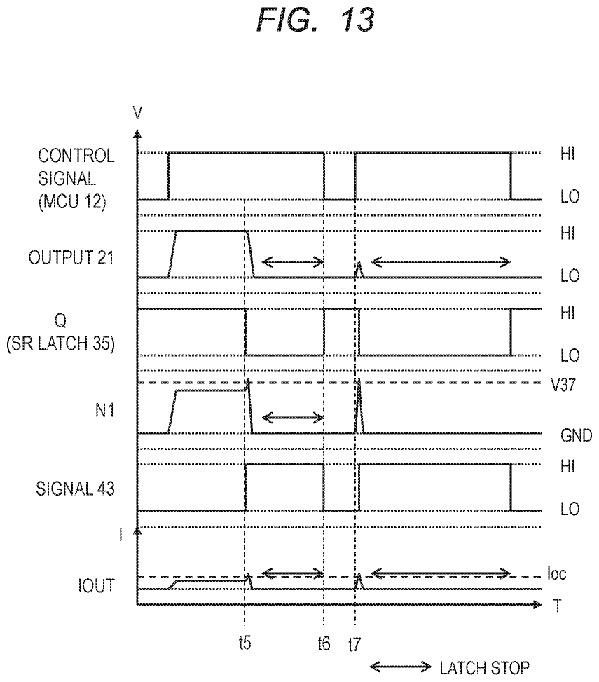

FIG. 13 is a timing chart when a short circuit fault occurs in the load 15 at second modified example. FIG. 13 shows that a short circuit fault occurred in the load 15 at time t5 in the same manner as in FIG. 9. At time t5, although the current IOUT increases, the voltage of the node N1 exceeds the voltage V37 when the current IOUT slightly increases. Since then, the operation of SR latch 35 and controller 34 is the same as the first embodiment. The details will not be described.

At a lower load current IOUT, a short circuit fault of the load 15 can be detected. This second modified example is enabled in applications where short-circuit fault detection is more critical than feedback control by MCU 12. Also, when inspecting the IPD using a semiconductor tester, conventionally it has to flow a large current to test the overcurrent detection function. This requires a large current measuring module, which increases the equipment cost. According to the present second modified example, it is possible to test the overcurrent detection function with a small current, facility cost, it is possible to keep the inspection cost low.

### Second Embodiment

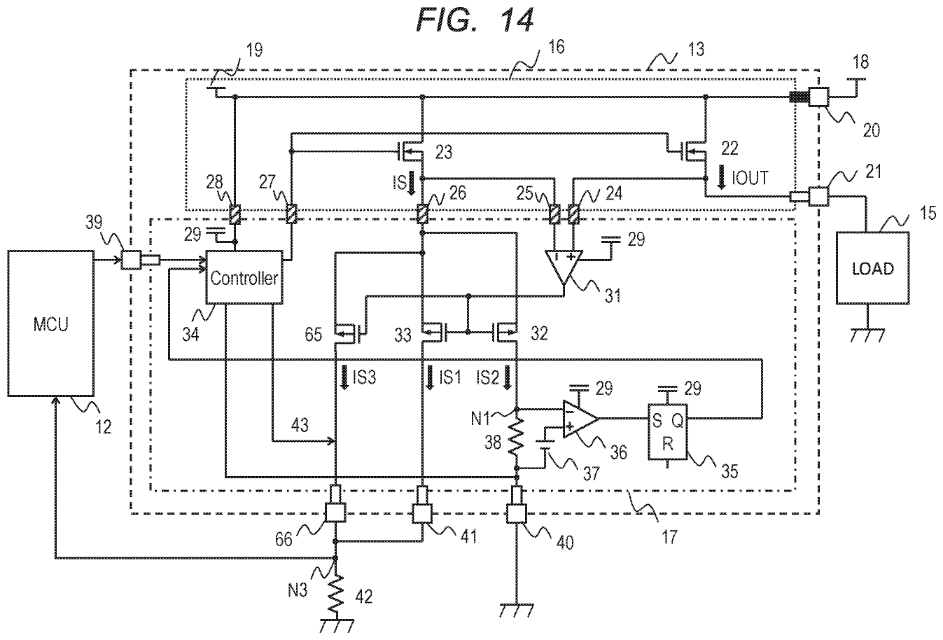

FIG. 14 is a detailed schematic diagram of an IPD 13 according to a second embodiment. The difference from FIG. 2 is that a P-type transistor 65 and an external terminal 66 are added. Transistor 65 is similar in structure to transistors 32, 33 and differs only in channel width. Transistor 65 can be said to be a third transistor. Transistor 65 is connected in parallel to transistors 32, 33.

The source of transistor 65 is connected to the source of the sense MOS 23 via the chip-chip bonding wire 26. The gate of transistor 65 is connected to the output of amplifier 31. External terminal 66 is connected to the drain of the transistor 65 via a lead-chip bonding wire.

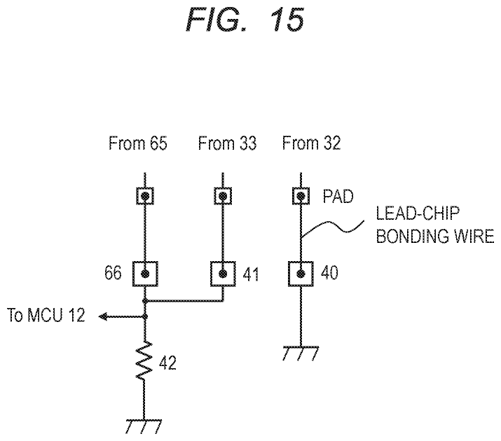

In FIG. 14, the external resistor 42 is connected to the external terminal 66 and the external terminal 41. The external terminal 40 is connected to the ground. By changing the connection of the terminals, it is possible to take various connection forms. Examples of connections are shown in FIGS. 15-20.

In FIG. 15, the external terminal 40 is connected to the ground. The external terminal 66 and the external terminal 41 are connected to the external resistor 42, and the connecting node is connected to MCU 12. In this case, the current IS flowing through the sense MOS 23 is divided into current IS1, IS2, IS3 according to the channel width of the transistors 32, 33, 65 (IS=IS1+IS2+IS3). Since IS1+IS2 flows through the external resistor 42, MCU 12 have an output current detecting capability corresponding to IS1+IS3. Further, the controller 34 have an overcurrent detecting capability corresponding to the current IS2.

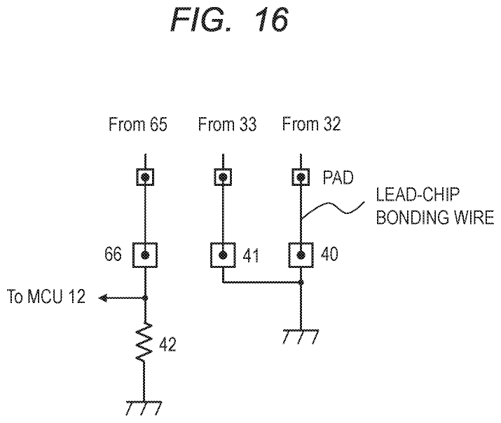

In FIG. 16, the external terminal 40 and the external terminal 41 are connected to the around. The external terminal 66 is connected to the external resistor 42, and the connecting node is connected to MCU 12. As in FIG. 15, IS=IS1+IS2+IS3. In this case, MCU 12 have an output current detecting capability corresponding to the current IS3. Further, the controller 34 have an overcurrent detecting capability according to the current IS2.

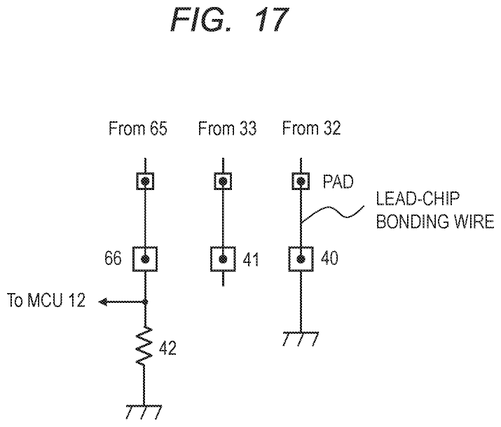

In FIG. 17, the external terminal 40 is connected to the ground. The external terminal 66 is connected to the external resistor 42, and the connecting node is connected to MCU 12. The external terminal 41 is not connected. In this situation, the current IS1 does not flow. MCU 12 have an output current sensing capability according to the current IS3. Further, the controller 34 have an overcurrent detecting capability according to the current IS2. However, since IS=IS2+IS3, IS2 (FIG. 17)>IS2 (FIG. 16) and IS3 (FIG. 17)>IS3 (FIG. 16) are satisfied.

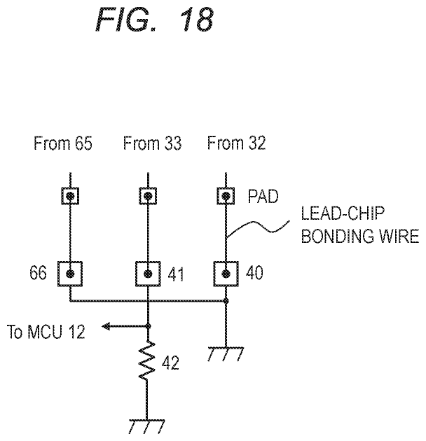

In FIG. 18, the external terminal 40 and the external terminal 66 are connected to the ground. The external terminal 41 is connected to the external resistor 42, and the connecting node is connected to MCU 12. As in FIGS. 15 and 16, IS=IS1+IS2+IS3. In this case, MCU 12 have an output current detecting capability corresponding to the current IS1. Further, the controller 34 have an overcurrent detecting capability according to the current IS2.

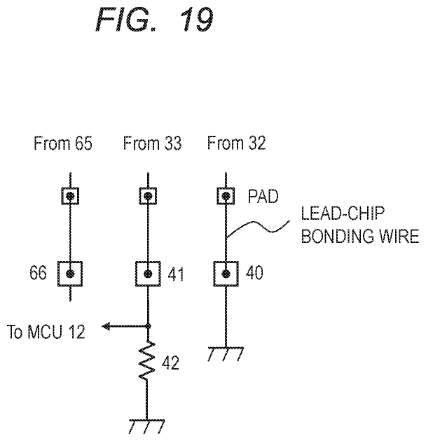

In FIG. 19, the external terminal 40 is connected to the ground. The external terminal 41 is connected to the external resistor 42, and the connecting node is connected to MCU 12. The external terminal 66 is not connected. In this situation, the current IS3 does not flow. MCU 12 have an output current sensing capability according to the current IS1. Further, the controller 34 have an overcurrent detecting capability according to the current IS2. However, since IS=IS1+IS2, IS1 (FIG. 19)>IS1 (FIG. 18) and IS2 (FIG. 19)>IS2 (FIG, 18) are satisfied.

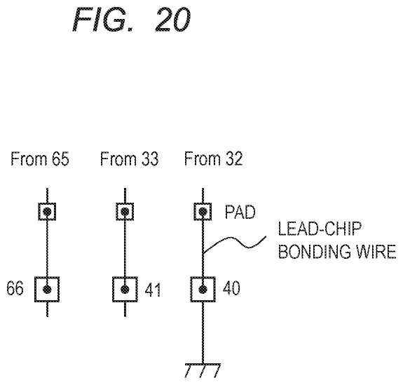

In FIG. 20, the external terminal 40 is connected to ground. External terminal 41 and the external terminal 66 are not connected. In this instance, the configuration is the same as that of second modified example of the first embodiment. That is, although MCU 12 cannot detect the output current, since IS=IS2, the controller 34 have the maximum overcurrent detection capability (the ability to detect the overcurrent with the minimum output current).

In FIGS. 15-20, the connection between the external terminals 40, 41, 66 and ground, external resistor 42, MCU 12 are changed. The same configuration can be realized by changing the connection of the lead-chip bonding wire.

Present embodiment connects three transistors 32, 33, 65 to the sense MOS 23, but not limited thereto. By increasing the number of transistors, it is possible to realize various output current/overcurrent detection capabilities.

As described above, in the electronic control device according to the second embodiment, by changing the connecting, it is possible to change the output current/overcurrent detecting capability. The output current/overcurrent sensing capability can be customized according to the type of load 15, the control methods for the load 15, and the resolution of the A/D converters included in MCU 12.

It should be noted that the present invention is not limited to the above-mentioned embodiments, and various modifications can be made without departing from the gist thereof.

What is claimed is:

1. A semiconductor device comprising:
an output transistor that supplies a power to a load;
a sense transistor that detects a load current of the output transistor;
first and second transistors connected in parallel to an output of the sense transistor;
an amplifier which has an inverting input coupled to an output of the output transistor, a non-inverting input coupled to the output of the sense transistor, and an output coupled to each gate of the first and second transistors;
a first voltage converter coupled to an output of the first transistor; and
a comparator that compares an output voltage of the first voltage converter with a predetermined voltage.

2. The semiconductor device according to claim 1, further comprising:
first and second semiconductor chips, wherein
the output transistor and the sense transistor are configured in the first semiconductor chip,
the first and second transistors, the amplifier, the first voltage converter and the comparator is configured in the second chip, and
the first and second chips are coupled by chip-chip bonding wires.

3. The semiconductor device according to claim 2, wherein an overcurrent to the load is detected based on a comparison result of the comparator.

4. The semiconductor device according to claim 3, further comprising:
a latch circuit coupled to an output of the comparator.

5. The semiconductor device according to claim 2, further comprising:
a controller that generates a gate drive signal of the output transistor and the sense transistor,
wherein the controller, when detecting an overcurrent to the load, turns off the output transistor and outputs an abnormality signal.

6. The semiconductor device according to claim 2, wherein an output of the second transistor is coupled to a second voltage converter.

7. The semiconductor device according to claim 2, further comprising:
a third transistor coupled in parallel to the first and second transistors.

8. The semiconductor device according to claim 2, wherein the output transistor has a similar structure to the sense transistor, and the first transistor has a similar structure to the second transistor.

9. The semiconductor device according to claim 3, wherein an ability to detect an overcurrent to the load is changed based on whether or not the output of the second transistor is coupled to the output of the first transistor.

10. A power device comprising:
a first power transistor that has a drain coupled to a power source, a gate to receive a control signal and supplies a power to a load;
a second power transistor that has a drain coupled to the power source and a gate to receive the control signal;
first and second transistors coupled in parallel to a source of the second power transistor;
an amplifier that has an inverting input coupled to a source of the first power transistor, a non-inverting input coupled to the source of the second power transistor and an output coupled to each gate of the first and second transistors;
a first voltage converter coupled to an output of the first transistor; and
a comparator that compares an output voltage of the first voltage converter with a predetermined voltage.

11. The power device according to claim 10, further comprising:
first and second semiconductor chips, wherein
the first and second power transistors are configured in the first chip,
the first and second transistors, the amplifier, the first voltage converter and the comparator is configured in the second chip, and
the first and second chips are coupled by chip-chip bonding wires.

12. The power device according to claim 11, wherein an overcurrent to the load is detected based on a comparison result of the comparator.

13. The power deice according to claim 11, further comprising:
a latch circuit coupled to an output of the comparator.

14. The power device according to claim 11, further comprising:
a controller that generates the control signal,
wherein the controller, when detecting an overcurrent to the load, turns off the first power transistor and outputs an abnormal signal.

15. The power device according to claim 11, wherein an output of the second transistor is coupled to a second voltage converter.

16. The power device according to claim 11, further comprising:
a third transistor coupled in parallel to the first and second transistors.

17. The power device according to claim 11, wherein the first power transistor has a similar structure to the second power transistor and the first transistor has a similar structure to the second transistor.

18. The power device according to claim 12, wherein an ability to detect an overcurrent to the load is changed based on whether or not the output of the second transistor is coupled to the output of the first transistor.
